(19) United States
(12) Patent Application Publication
(10) Pub. No.: US 2009/0250503 A1
(43) Pub. Date: Oct. 8, 2009

(54) Z-AXIS MOTION SYSTEM FOR A WIRE BONDING MACHINE

(75) Inventors: Michael P. Schmidt-Lange, North Wales, PA (US); Stephen M. Jaeschke, Horsham, PA (US)

Correspondence Address: KULICKE AND SOFFA INDUSTRIES, INC., 1005 VIRGINIA DRIVE, FORT WASHINGTON, PA, 19034, US

(73) Assignee: KULICKE AND SOFFA INDUSTRIES, INC., Fort Washington, PA (US)

(21) Appl. No.: 11/817,882

(22) PCT Filed: Aug. 30, 2006
(86) PCT No.: PCT/US2006/033852

§ 371 Date: Sep. 6, 2007

(51) Int. Cl. B23K 1/06

(52) U.S. Cl. 228/1.1

(57) ABSTRACT

A coil assembly configured to provide motion of a bonding tool of a wire bonding machine along a substantially vertical axis is provided. The coil assembly includes a first coil portion having a first force constant, the first coil portion being configured to receive energy to provide a first motion of the bonding tool. The coil assembly also includes a second coil portion having a second force constant, the second coil portion being configured to receive energy to provide a second motion of the bonding tool, the second force constant being different from the first force constant.

### FIELD OF THE INVENTION

The present invention relates to wire bonding of semiconductor devices, and more particularly, to providing an improved z-axis motion system for a wire bonding machine.

### BACKGROUND OF THE INVENTION

Wire bonders (i.e., wire bonding machines) typically include a vertical or substantially vertical motion axis that carries components such as a bonding tool (e.g., a capillary tool), an ultrasonic transducer (if used), a wire clamp, etc. This motion axis is commonly referred to as the “z-axis” and is utilized to position the bonding tool for bonding, looping, ball formation (e.g., via electric flame-off, etc.), and is also utilized to apply a controlled force during bonding (“bond force” or “bonding force”).

Conventionally, the force utilized for motion in the z-axis, as well as the bond force, is applied by a motor. For example, in certain motors, a current is passed through a coil to produce the force to move along the z-axis. In such a configuration, either the coil or a permanent magnet assembly included in the motor may be the component that moves along the z-axis.

FIGS. 1A-1B are perspective and side views of a conventional bond head assembly of a wire bonder, respectively. In the art, the terms “bond head” and/or “bondhead” are sometimes used to refer to structures similar to that illustrated in FIGS. 1A-1B; however, sometimes the terms are used to refer to structures having additional or fewer components. In the present application, the terms “bond head”, “bondhead”, “bond head assembly”, and “bondhead assembly” are intended to refer to any structure which supports a bonding tool (directly or via other components) in a bonding machine (e.g., a wire bonding machine, a stud bumping machine, etc.).

Support structure 10 (e.g., bond head link 10) carries ultrasonic transducer 20 which in turn carries bonding tool 30 (e.g., capillary 30). Bond head link 10 also carries wire clamp assembly 40. In FIGS. 1A-1B, the stationary portion of motor 50 for providing motion along the z-axis is permanent magnet assembly 52. Permanent magnet assembly 52 includes left magnet portion 52a and right magnet portion 52b (right magnet portion 52b is removed for clarity in FIG. 1B). Permanent magnet assembly 52 is rigidly mounted to a larger supporting structure of a wire bonding machine (not shown), where the wire bonding machine (and perhaps the same larger supporting structure) also supports rotational motion about rotational axis 80. The z-motion is provided by pivoting about rotational axis 80 to provide substantially vertical motion of bonding tool 30. Coil 60 (e.g., a coil including a number of conductive turns) is rigidly connected to bond head link 10. Lead wires 62a and 62b are electrically coupled to coil 60. A control system (not shown) passes current through coil 60 (via lead wires 62a and 62b) to produce a force along the z-axis. Control of the current through coil 60 provides for both motion control and bond force application. Position measurement device 70 (e.g., encoder 70) is used, for example, in conjunction with a servo control system, to achieve position control.

It is desirable for the z-axis to be configured for rapid motion, for example, between a bonding position and ball formation (e.g., EFO) position, and to provide an accurate force during bonding. The force used during bonding is substantially lower than the force used to accelerate along the z-axis during high speed motions, and is desirably substantially more accurate. The operation of a wire bonder would desirably provide (1) high motor force during acceleration and deceleration, and (2) accurate control of a significantly smaller force for bond force application. Unfortunately, conventional motors do not adequately provide for these desirable features.

For example, a small error in applied current with respect to the total current range may be a large portion of the desired current during bond force control. Further, it may be impractical to reduce such fixed current errors (e.g., an error caused by thermal drift in the motor amplifier) to a sufficiently low level to achieve the desired bond force accuracy with a motor that is also suitable for high speed motions. Further still, more powerful motors (e.g., motors that are desirable for high acceleration and motion performance) tend to have correspondingly larger force errors due to the fixed current errors.

Thus, it would be desirable to provide an improved motion system for the z-axis of a wire bonder.

### SUMMARY OF THE INVENTION

According to an exemplary embodiment of the present invention, a coil assembly configured to provide motion of a bonding tool of a wire bonding machine along a substantially vertical axis is provided. The coil assembly includes a first coil portion having a first force constant. The first coil portion is configured to receive energy to provide a first force to the bonding tool. The coil assembly also includes a second coil portion having a second force constant. The second coil portion is configured to receive energy to provide a second force to the bonding tool. The second force constant is different from the first force constant.

According to another exemplary embodiment of the present invention, a bond head assembly for a wire bonding machine is provided. The bond head assembly includes a bonding tool and a coil assembly. The coil assembly includes a first coil portion having a first force constant. The first coil portion is configured to receive energy to provide a first force to the bonding tool. The coil assembly also includes a second coil portion having a second force constant. The second coil portion is configured to receive energy to provide a second force to the bonding tool. The second force constant is different from the first force constant.

According to yet another exemplary embodiment of the present invention, a wire bonding machine is provided. The wire bonding machine includes a support structure and a bond head assembly. The bond head assembly includes a bonding tool and a coil assembly. The coil assembly includes a first coil portion having a first force constant. The first coil portion is configured to receive energy to provide a first force to the bonding tool. The coil assembly also includes a second coil portion having a second force constant. The second coil portion is configured to receive energy to provide a second force to the bonding tool. The second force constant is different from the first force constant. The bond head assembly is rotatably supported by the support structure to provide for a substantially vertical motion of a bonding tool.

### BRIEF DESCRIPTION OF THE DRAWINGS

The invention is best understood from the following detailed description when read in connection with the accompanying drawing. It is emphasized that, according to common practice, the various features of the drawing are not to scale. On the contrary, the dimensions of the various features are arbitrarily expanded or reduced for clarity. Included in the drawing are the following figures:

FIG. 1A is a perspective view of a prior art bond head assembly of a wire bonding machine;

FIG. 1B is a side view of the bond head assembly of FIG. 1A with lead wires connected to a coil of the bond head assembly;

FIG. 2A is a perspective view of a bond head assembly of a wire bonding machine in accordance with an exemplary embodiment of the present invention;

FIG. 2B is a side view of the bond head assembly of FIG. 2A with lead wires connected to a coil assembly of the bond head assembly;

FIG. 3A is a perspective view of a coil assembly in accordance with an exemplary embodiment of the present invention;

FIG. 3B is a perspective view of another coil assembly in accordance with another exemplary embodiment of the present invention;

FIG. 3C is a perspective view of another coil assembly in accordance with yet another exemplary embodiment of the present invention;

FIG. 3D is a perspective view of another coil assembly in accordance with yet another exemplary embodiment of the present invention;

FIG. 4A is a schematic representation of a prior art coil assembly;

FIG. 4B is a schematic representation of a coil assembly in accordance with an exemplary embodiment of the present invention;

FIG. 4C is a schematic representation of a coil assembly in accordance with another exemplary embodiment of the present invention;

FIG. 4D is a schematic representation of a coil assembly in accordance with another exemplary embodiment of the present invention; and

FIG. 5 is a perspective view of a portion of a wire bonding machine in accordance with an exemplary embodiment of the present invention.

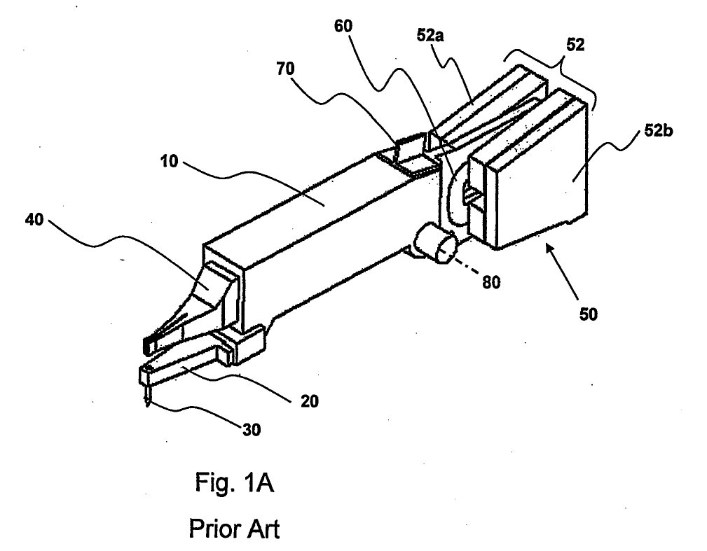

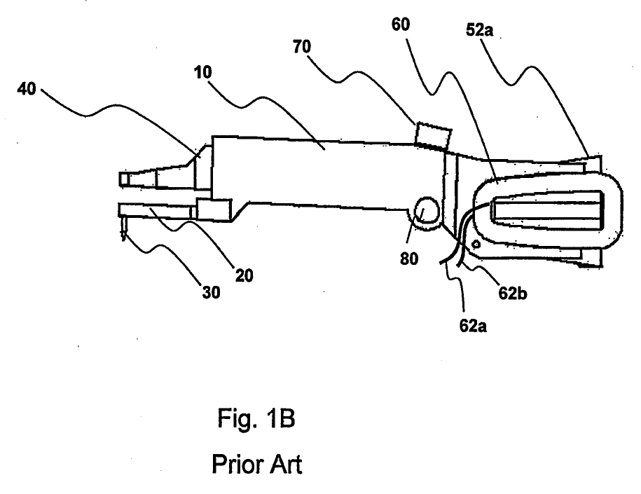

### DETAILED DESCRIPTION OF THE INVENTION

According to the present invention, an improved coil assembly for the z-axis of a wire bonding machine is provided.

In the present application a system for moving a bonding tool along a substantially vertical axis (e.g., the z-axis) is provided. Often, the motion along the substantially vertical axis is provided by a pivoting motion of a bond head assembly or the like (which supports the bonding tool), where the pivoting motion of the bond head assembly with respect. to a support structure of a wire bonding machine results in substantially vertical motion of the bonding tool; however, the present application also contemplates other motions than pivoting motions (e.g., a linear motion) of the bond head assembly to provide the substantially vertical motion of the bonding tool.

According to an exemplary embodiment of the present invention, the force accuracy of a z-axis motor is improved, without a corresponding increase in dynamic range or accuracy of the current supplied by the controlling electronics. According to the present invention, this is achieved by separating the z-axis motor coil into a first segment (e.g., a larger segment) for use when relatively high forces are desired, and a second segment (e.g., a smaller segment) with a substantially smaller force constant for use when fine force control is desired. In such an exemplary embodiment, the first segment may have a different (e.g., higher) force constant than the second segment. As is known to those skilled in the art, the force constant may be at least partially controlled by the number of turns of conductor (e.g., wire) in a coil portion, and as such, in order to provide a first coil portion with a higher force constant than a second coil portion, the first coil portion may have more turns than the second coil portion.

These two segments may be, for example, (1) 2 separate motors (e.g., one with a substantially lower force constant than the other), (2) segments/portions of a single coil assembly operating in conjunction with a single external magnetic field assembly where each segment has separate input/output leads, or (3) segments/portions of a single coil assembly operating in conjunction with a single external magnetic field assembly where the segments share at least one input/output lead (e.g., there is provided a third lead wire that is positioned within the windings of the coil assembly such as to allow current to pass only through a portion of the windings).

For example, current may be passed through the coil assembly using an electronic controller under software control in a number of ways. According to one example, this could be accomplished by passing current through all of the windings of the coil assembly for high-speed motions and/or high-acceleration/deceleration motions, and passing current through a portion of the windings of the coil assembly (e.g., a smaller coil segment) for fine force control. According to another example, this could be accomplished using two different coil segments: a larger segment of the coil assembly being used for high-speed and/or high-acceleration/deceleration motions, and a smaller segment of the coil assembly being used for fine force control. In some phases of operation, current may be passed in a controlled manner through both segments, such as during the transition from one mode of operation to another.

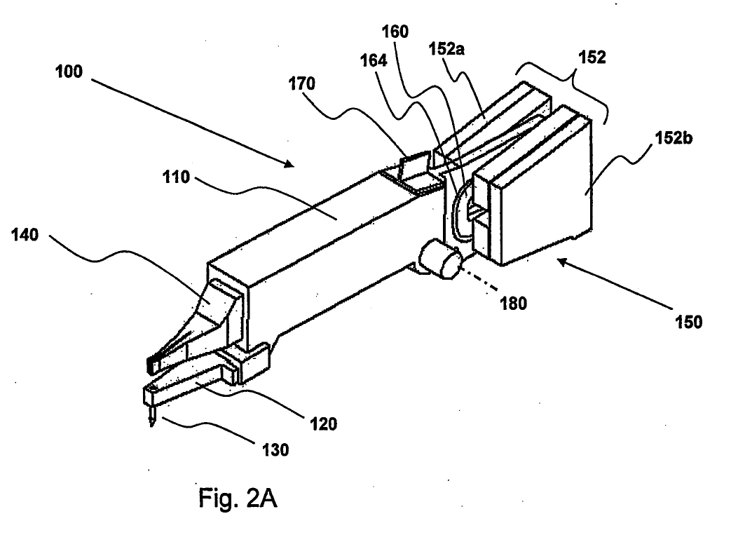

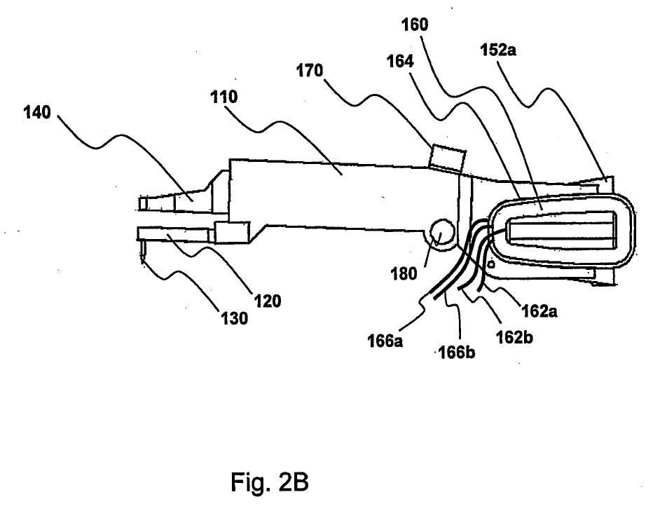

FIGS. 2A-2B illustrate perspective and side views of bond head assembly 100 (e.g., configured for use in a wire bonding machine) in accordance with an exemplary embodiment of the present invention. As shown in FIG. 2A, bond head link (a supporting member for the bond head) 110 carries ultrasonic transducer 120, which in turn carries bonding tool 130 (e.g., a capillary 130). Bond head link 110 also carries wire clamp assembly 140. In the exemplary embodiment of the present invention illustrated in FIGS. 2A-2B, a stationary part of motor 150 is permanent magnet assembly 152, including left magnet portion 152a and right magnet portion 152b (right magnet portion 152b is removed for clarity in FIG. 2B). Permanent magnet assembly 152 is rigidly mounted to a larger supporting structure of a wire bonding machine (not shown in FIGS. 2A-2B), where the wire bonding machine (e.g., via the larger supporting structure of the wire bonding machine) pivotally supports bond head link 110 about rotational axis 180, where z-motion is provided by pivotal motion about rotational axis 180 to achieve substantially vertical motion of bonding tool 130. FIGS. 2A-2B also illustrate position measurement device 170 (e.g., encoder 170) which is used, for example, in conjunction with a servo control system, to achieve position control.

In the exemplary embodiment of the present invention illustrated in FIGS. 2A-2B, primary motor coil portion 160 (e.g., comprised of a number of turns of wire) is rigidly connected to bond head link 110 and features lead wires 162a and 162b which are connected to the controlling electronics and allow current to be passed through the coil windings of primary coil portion 160 in order to. produce a force on the z-axis. Secondary motor coil portion 164 (e.g., comprised of a smaller number of turns than primary motor coil portion 160) features lead wires 166a and 166b which are also connected to the controlling electronics, but separately controlled. Each of primary and secondary coil portions 160 and 164 pass through substantially the same external magnetic field created by magnet assembly 150, and as such, secondary coil portion 164 (with fewer turns of wire than primary coil portion 160) will have a smaller force output (compared to primary coil portion 160) for the same input current. This allows secondary coil portion 164 to be able to provide more accurate control of bond force given a constant current error in the controlling electronics.

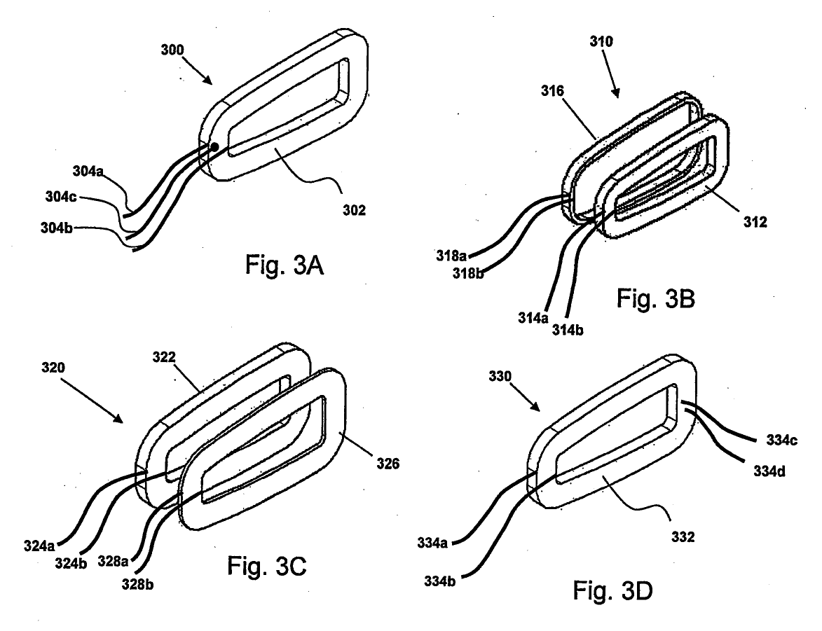

In the exemplary embodiment of the present invention illustrated in FIGS. 2A-2B, a single coil assembly [including a first (primary) coil portion 160 and a second (secondary) coil portion 164] is provided in a single magnetic filed (generated by permanent magnet assembly 152); however, a number of different motor/coil configurations may be utilized. FIGS. 3A-3C illustrate three different potential configurations; however, other configurations are contemplated.

Referring now to FIG. 3A, coil assembly 300 includes windings 302 and leads 304a, 304b, and 304c. For example, leads 304a and 304b may be input/output leads for the entire windings 302 (e.g., a first coil portion to be used for the high speed and/or high acceleration/deceleration motions of a bonding tool) while leads 304a and 304c may be input/output leads for a portion of windings 302 (e.g., a second coil portion to be used for bond force motions). Effectively, lead wire 304c is connected at an intermediate winding in windings 302, such that passing current between leads 304a and 304c (or between 304b and 304c) will pass current through a smaller number of turns (i.e., smaller than all of the turns of the entire winding), effectively acting as a secondary coil for the purposes of finer force control.

FIG. 3B illustrates coil assembly 310 including first coil portion 312 and second coil portion 316. Coil portions 312 and 316 are configured to be engaged in a concentric arrangement (similar to the concentric arrangement of coil portions 160 and 164 in FIG. 2B). As shown in FIG. 3B, first coil portion 312 (e.g.; a first coil portion to be used for the high speed motions of a bonding tool) includes leads 314a and 314b which are input/output leads for supplying an electrical current to first coil portion 312. Second coil portion 316 (e.g., a second coil portion to be used for bond force motions) includes leads 318a and 318b which are input/output leads for supplying an electrical current to second coil portion 316.

FIG. 3C illustrates coil assembly 320 including first coil portion 322 and second coil portion 326. Coil portions 322 and 326 are configured to be engaged in a side-by-side (or stacked) arrangement. As shown in FIG. 3C, first coil portion 322 (e.g., a first coil portion to be used for the high speed motions of a bonding tool) includes leads 324a and 324b which are input/output leads for supplying an electrical current to first coil portion 322. Second coil portion 326 (e.g., a second coil portion to be used for bond force motions) includes leads 328a and 328b which are input/output leads for supplying an electrical current to second coil portion 326.

FIG. 3D illustrates coil assembly 330 includes windings 332 and leads 334a, 334b, 334c, and 334d. For example, leads 334a and 334b may be input/output leads for the entire windings 332 (e.g., a first coil portion to be used for the high speed and/or high acceleration/deceleration motions of a bonding tool) while leads 334c and 334d may be input/output leads for a portion of windings 332 (e.g., a second coil portion to be used for bond force motions). Effectively, lead wires 334c and 334d are connected at intermediate windings in windings 332, such that passing current between leads 334c and 334d will pass current through a smaller number of turns (i.e., smaller than all of the turns of the entire winding), effectively acting as a secondary coil for the purposes of finer force control. In certain applications, this configuration may be preferred to the exemplary embodiment illustrated in FIG. 3A, for example, because of potential force constant linearity benefits and the like.

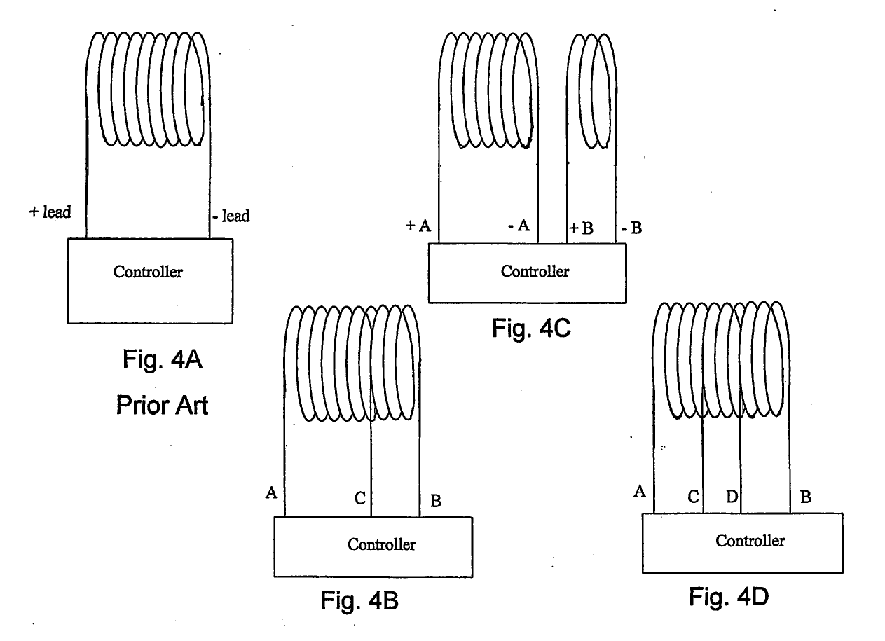

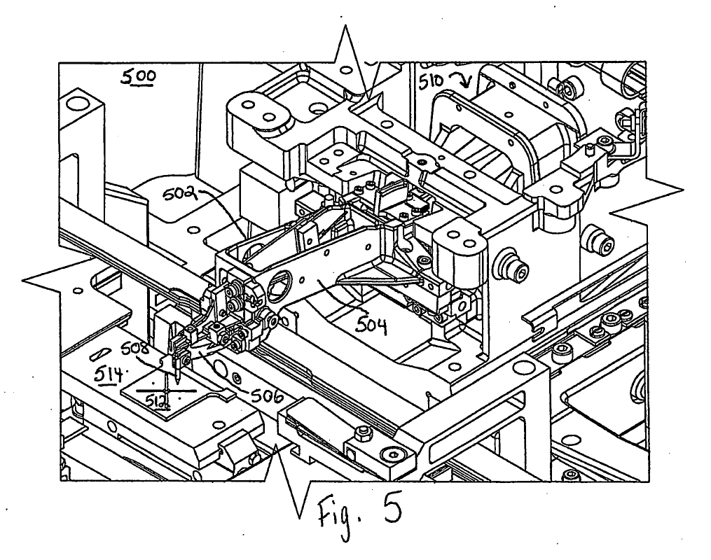

FIGS. 4A-4D are simplified schematic views of a number of coil assemblies. FIG. 4A is a prior art coil schematic where a controller supplies a current to a single coil for all motions in the z-axis including, for example, high speed z-axis motions, as well as bond force motions. FIG. 4B (which includes input leads A, B, and C) includes intermediate lead C (which may be fixedly connected to a winding of the coil, or may be a variable connection for varying the winding position of lead C) such that two current paths are provided (e.g., a complete winding current path from lead A to lead B, and a partial winding current path from lead c to lead B). Thus, FIG. 4B is similar to the arrangement shown in FIG. 3A. FIG. 4C illustrates two distinct coil portions where a first coil portion includes leads +A and −A, and a second coil portion includes leads +B and −B. FIG. 4C is similar to the arrangement shown in either of FIGS. 3B-3C. FIG. 4D is similar to the arrangement shown in FIG. 3D, where leads A and B are input/output leads for the complete winding current path, while leads C and D are input/output leads for a partial winding current path.

FIG. 5 is a diagram of a portion of wire bonding machine 500, with certain parts removed for clarity. Wire bonding machine 500 includes bond head assembly 502 including bond head link 504. Bond head link 504 supports transducer 506 which supports bonding tool 508. Bonding tool 508 is used to create wire bonds at bond site 512. Bond site 512 is illustrated adjacent heat block insert 514. Also included in bond head assembly 502 is z-axis motor assembly 510, which may be, for example, a motor as illustrated and described above by reference to FIGS. 2A-2B and 3A-3C.

By separating the z-axis force control between different coil portions in accordance with certain exemplary embodiments of the present invention, a number of advantages are achieved. For example, a higher maximum z-motor force (with increased acceleration for high speed motions) is provided, while at the same time, finer control of the z-motor force is also provided for bond force accuracy and the like. More specifically, the force constant of a larger coil portion (or in certain embodiments, the complete coil) can be raised in comparison to prior z-axis coils without adversely affecting the force accuracy for relatively static forces such as bond forces because of the inclusion of a smaller coil portion.

In general, the power applied to a z-axis motor according to the present invention is direct current; however, it is contemplated that the teachings of the present invention are also applicable to an alternating current based system.

While the present invention has been described primarily in terms of coil portions of a coil assembly having different force constants, it is contemplated that the coil portions could have the same (or substantially the same) force constant, but be maintained by a control system to provide different force outputs as is desired in the bonding system.

While the present invention is described primarily in terms of a coil assembly having two coil portions, it is contemplated that three or more coil portions could be included to provide for additional separate control of the bonding tool.

Although the invention is illustrated and described herein with reference to specific embodiments, the invention is not intended to be limited to the details shown. Rather, various modifications may be made in the details within the scope and range of equivalents of the claims and without departing from the invention.

1. A coil assembly configured to provide motion of a bonding tool of a wire bonding machine along a substantially vertical axis, the coil assembly comprising:
a first coil portion having a first force constant, the first coil portion being configured to receive energy to provide a first force to the bonding tool; and
a second coil portion having a second force constant, the second coil portion being configured to receive energy to provide a second force to the bonding tool, the second force constant being different from the first force constant.

2. (canceled)

3. The coil assembly of claim 1 wherein the first coil portion includes a first input lead and first output lead, the second coil portion includes a second input lead and second output lead, wherein one of the first input lead and the first output lead is substantially electrically equivalent to one of the second input lead and second output lead.

4. (canceled)

5. (canceled)

6. The coil assembly of claim 1 wherein the first force provides for high acceleration motions of the bonding tool, and the second force provides a bonding force of the bonding tool.

7. The coil assembly of claim 1 wherein the substantially vertical axis is the z-axis of the wire bonding machine.

8. The coil assembly of claim 1 wherein each of the first coil portion and the second coil portion is configured to pass through a single magnetic field.

9. The coil assembly of claim 8 wherein the first coil portion is larger than the second coil portion such that when an identical magnitude of current is applied to each of the first coil portion and the second coil portion, the first coil portion produces a larger force output in comparison to the second portion.

10. The coil assembly of claim 1 wherein the second coil portion is part of the first coil portion.

11. The coil assembly of claim 1 wherein the first coil portion is distinct from the second coil portion.

12. A bond head assembly configured to be included in a wire bonding machine, the bond head assembly comprising:
a bonding tool; and
a coil assembly, the coil assembly including a first coil portion having a first force constant, the first coil portion being configured to receive energy to provide a first force to the bonding tool, the coil assembly also including a second coil portion having a second force constant, the second coil portion being configured to receive energy to provide a second force to the bonding tool, the second force constant being different from the first force constant.

13. (canceled)

14. (canceled)

15. (canceled)

16. The bond head assembly of claim 12 wherein the first coil portion includes a first input lead and first output lead, the second coil portion includes a second input lead and second output lead, wherein one of the first input lead and the first output lead is substantially electrically equivalent to one of the second input lead and second output lead.

17. (canceled)

18. (canceled)

19. The bond head assembly of claim 12 wherein the first force provides for high acceleration motions of the bonding tool, and the second force provides a bonding force of the bonding tool.

20. The bond head assembly of claim 12 wherein the substantially vertical axis is the z-axis of the wire bonding machine.

21. The bond head assembly of claim 12 further comprising a magnet assembly providing a magnetic field, wherein each of the first coil portion and the second coil portion is configured to pass through the magnetic field.

22. The bond head assembly of claim 21 wherein the first coil portion is larger than the second coil portion such that when an identical magnitude of current is applied to each of the first coil portion and the second coil portion, the first coil portion produces a larger force output in comparison to the second portion.

23. The bond head assembly of claim 12 wherein the second coil portion is part of the first coil portion.

24. The bond head assembly of claim 12 wherein the first coil portion is distinct from the second coil portion.

25. A wire bonding machine comprising:
a support structure; and
a bond head assembly, the bond head assembly including a bonding tool and a coil assembly, the coil assembly including a first coil portion having a first force constant, the first coil portion being configured to receive energy to provide a first force to the bonding tool, the coil assembly also including a second coil portion having a second force constant, the second coil portion being configured to receive energy to provide a second force to the bonding tool, the second force constant being different from the first force constant,
the bond head assembly being rotatably supported by the support structure to provide for a substantially vertical motion of a bonding tool.

26. (canceled)

27. (canceled)

28. (canceled)

29. The wire bonding machine of claim 25 wherein the first coil portion includes a first input lead and first output lead, the second coil portion includes a second input lead and second output lead, wherein one of the first input lead and the first output lead is substantially electrically equivalent to one of the second input lead and second output lead.

30. (canceled)

31. (canceled)

32. The wire bonding machine of claim 25 wherein the first force provides for high acceleration motions of the bonding tool, and the second force provides a bonding force of the bonding tool.

33. The wire bonding machine of claim 25 wherein the substantially vertical axis is the Z-axis of the wire bonding machine.

34. The wire bonding machine of claim 25 wherein the bond head assembly further comprises a magnet assembly providing a magnetic field, each of the first coil portion and the second coil portion being configured to pass through the magnetic field.

35. The wire bonding machine of claim 34 wherein the first coil portion is larger than the second coil portion such that when an identical magnitude of current is applied to each of the first coil portion and the second coil portion, the first coil portion produces a larger force output in comparison to the second portion.

36. The wire bonding machine of claim 25 wherein the second coil portion is part of the first coil portion.

37. The wire bonding machine of claim 25 wherein the first coil portion is distinct from the second coil portion.
